(19) United States
(12) Patent Application Publication
(10) Pub. No.: US 2026/0353558 A1
(43) Pub. Date: Nov. 5, 2026

(54) WIRING SUBSTRATE

(71) Applicant: IBIDEN CO., LTD., Gifu (JP)

(72) Inventors: Nobuhisa KURODA, Gifu (JP); Ayami OHNO, Gifu (JP)

(73) Assignee: IBIDEN CO., LTD., Gifu (JP)

(21) Appl. No.: 19/401,689

(22) Filed: Nov. 26, 2025

(30) Foreign Application Priority Data
Dec. 6, 2024 (JP) 2024-212997

(51) Int. Cl. H05K 1/11; H05K 1/03

(52) U.S. Cl. CPC H05K 1/115; H05K 1/0306

(57) ABSTRACT

A wiring substrate includes a core substrate including a through-hole conductor, a resin insulating layer formed on the core substrate, a first conductor layer formed on a surface of the resin insulating layer, and a via conductor formed in the resin insulating layer such that the via conductor is connected to the through-hole conductor of the core substrate. The core substrate is formed such that the core substrate includes a substrate including glass and the through-hole conductor formed in the substrate and that the through-hole conductor has an end surface formed below a surface of the substrate.

### CROSS-REFERENCE TO RELATED APPLICATIONS

The present application is based upon and claims the benefit of priority to Japanese Patent Application No. 2024-212997, filed Dec. 6, 2024, the entire contents of which are incorporated herein by reference.

### BACKGROUND OF THE INVENTION

### Field of the Invention

The present invention relates to a wiring substrate.

### Description of Background Art

Japanese Patent Application Laid-Open Publication No. 2024-118643 describes a wiring substrate having a core substrate and build-up layers. The entire contents of this publication are incorporated herein by reference.

### SUMMARY OF THE INVENTION

According to one aspect of the present invention, a wiring substrate includes a core substrate including a through-hole conductor, a resin insulating layer formed on the core substrate, a first conductor layer formed on a surface of the resin insulating layer, and a via conductor formed in the resin insulating layer such that the via conductor is connected to the through-hole conductor of the core substrate. The core substrate is formed such that the core substrate includes a substrate including glass and the through-hole conductor formed in the substrate and that the through-hole conductor has an end surface formed below a surface of the substrate.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a wiring substrate according to an embodiment of the present invention;

FIGS. 2A-2C illustrate partial enlarged views of a wiring substrate according to an embodiment of the present invention;

FIG. 3A is a cross-sectional view schematically illustrating a method for manufacturing a wiring substrate according to an embodiment of the present invention;

FIG. 3B is a cross-sectional view schematically illustrating a method for manufacturing a wiring substrate according to an embodiment of the present invention;

FIG. 3C is a cross-sectional view schematically illustrating a method for manufacturing a wiring substrate according to an embodiment of the present invention;

FIG. 3D is a cross-sectional view schematically illustrating a method for manufacturing a wiring substrate according to an embodiment of the present invention;

FIG. 3E is a cross-sectional view schematically illustrating a method for manufacturing a wiring substrate according to an embodiment of the present invention;

FIG. 3F is a cross-sectional view schematically illustrating a method for manufacturing a wiring substrate according to an embodiment of the present invention;

FIG. 3G is a cross-sectional view schematically illustrating a method for manufacturing a wiring substrate according to an embodiment of the present invention;

FIG. 3H is a cross-sectional view schematically illustrating a method for manufacturing a wiring substrate according to an embodiment of the present invention; and

FIG. 3I is a cross-sectional view schematically illustrating a method for manufacturing a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

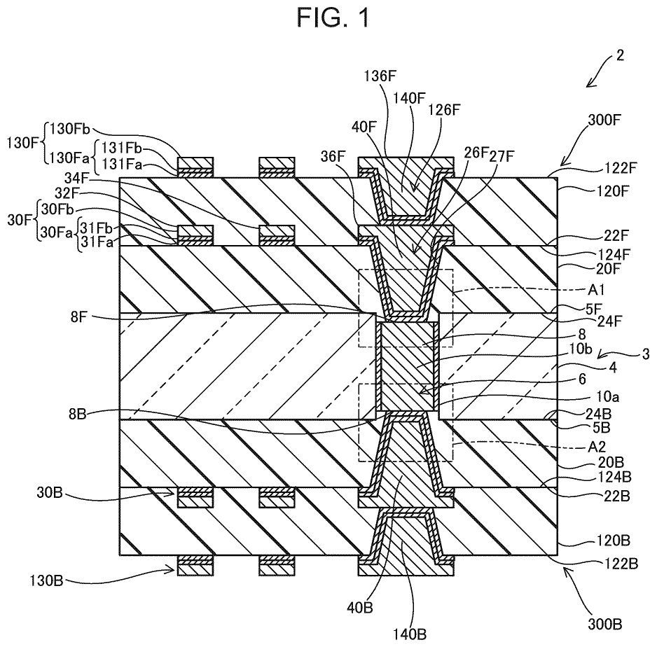

FIG. 1 is a cross-sectional view illustrating a wiring substrate 2 according to an embodiment of the present invention. As illustrated in FIG. 1, the wiring substrate 2 includes a core substrate 3, a front-side build-up layer (300F), and a back-side build-up layer (300B). The core substrate 3 includes a substrate 4, a through hole 6, and a through-hole conductor 8. The substrate 4 has a front surface (5F) and a back surface (5B) on a side opposite to the front surface (5F). The core substrate 3 has a front surface (5F) and a back surface (5B) on a side opposite to the front surface (5F). The front surface (5F) of the core substrate 3 and the front surface (5F) of the substrate 4 are the same surface. The back surface (5B) of the core substrate 3 and the back surface (5B) of the substrate 4 are the same surface. The front surface (5F) is closer to a mounting surface than the back surface (5B). An electronic component is mounted on the front-side build-up layer (300F).

The front-side build-up layer (300F) is formed on the front surface (5F) of the substrate 4. The front-side build-up layer (300F) includes front-side resin insulating layers, front-side conductor layers, and front-side via conductors that penetrate the front-side resin insulating layers. The front-side conductor layers and the front-side via conductors are electrically connected to the through-hole conductor 8. The front-side resin insulating layers and the front-side conductor layers are alternately laminated. The front-side resin insulating layers in FIG. 1 are a first resin insulating layer (front-side first resin insulating layer) (20F) and a second resin insulating layer (front-side second resin insulating layer) (120F). The front-side conductor layers are a first conductor layer (front-side first conductor layer) (30F) and a second conductor layer (front-side second conductor layer) (130F). The front-side via conductors are a first via conductor (front-side first via conductor) (40F) and a second via conductor (front-side second via conductor) (140F). The number of the resin insulating layers and conductor layers forming the front-side build-up layer (300F) may be 3 or more.

The back-side build-up layer (300B) is formed on the back surface (5B) of the substrate 4. The back-side build-up layer (300B) includes back-side resin insulating layers, back-side conductor layers, and back-side via conductors that penetrate the back-side resin insulating layers. The back-side resin insulating layers and the back-side conductor layers are alternately laminated. The back-side conductor layers and the back-side via conductors are electrically connected to the through-hole conductor 8. The back-side resin insulating layers in FIG. 1 are a first resin insulating layer (back-side first resin insulating layer) (20B) and a second resin insulating layer (back-side second resin insulating layer) (120B). The back-side conductor layers are a first conductor layer (back-side first conductor layer) (30B) and a second conductor layer (back-side second conductor layer) (130B). The back-side via conductors are a first via conductor (back-side first via conductor) (40B) and a second via conductor (back-side second via conductor) (140B). The number of the resin insulating layers and conductor layers forming the back-side build-up layer (300B) may be 3 or more.

The substrate 4 is made of glass. The through hole 6 penetrates the substrate 4. The through hole 6 has a substantially cylindrical shape. The through hole 6 has a substantially constant diameter. It is also possible that the through hole 6 has a substantially truncated cone shape. It is also possible that the through hole 6 has a shape obtained by connecting two substantially conical shapes. The two cones are a front-surface side cone and a back-surface side cone. A bottom surface of the front-surface side cone is positioned on the front surface (5F), and a bottom surface of the back-surface side cone is positioned on the back surface (5B). In this case, a side surface of the through hole 6 is formed of a surface tapering from the front surface (5F) toward the back surface (5B) and a surface tapering from the back surface (5B) toward the front surface (5F).

The through-hole conductor 8 is formed in the through hole 6. The through-hole conductor 8 is mainly formed of copper. The through-hole conductor 8 includes a seed layer (10a) formed on an inner wall surface of the through hole 6 and an electrolytic plating layer (10b) formed on the seed layer (10a). The electrolytic plating layer (10b) fills the through hole 6. The seed layer (10a) is formed by electroless plating. The through-hole conductor 8 has an end surface (8F) on the front surface (5F) side and an end surface (8B) on the back surface (5B) side.

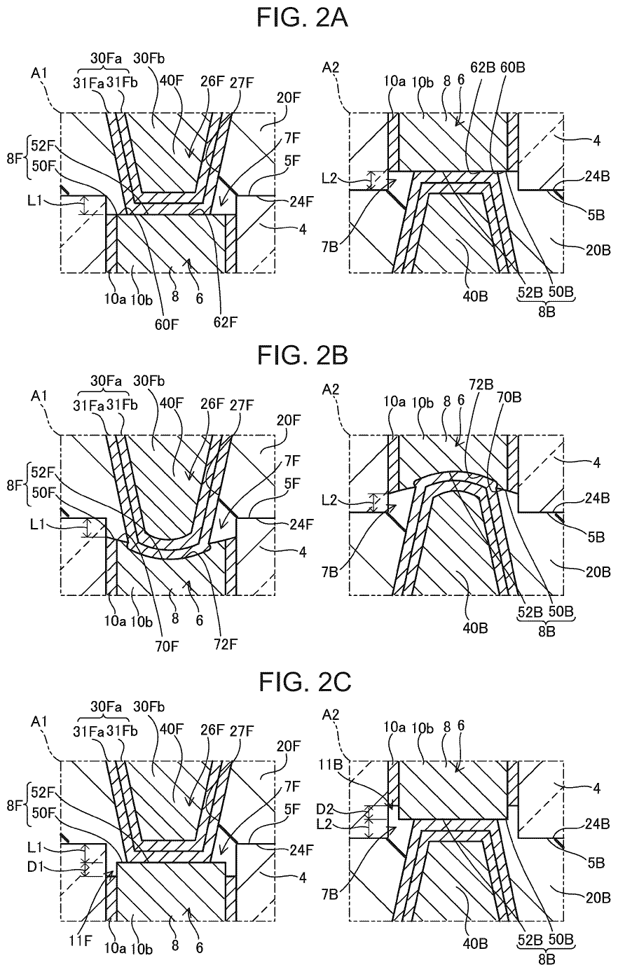

FIG. 2 illustrates enlarged views of a portion (A1) and a portion (A2) in FIG. 1. As illustrated in FIG. 2A, the end surface (8F) is formed below the front surface (5F). The end surface (8B) is formed below the back surface (5B). The end surface (8F) and the end surface (8B) are formed in the substrate 4. In the embodiment, on the end surface (8F), there is a recess (front-side recess) (7F) surrounded by the end surface (8F) and the inner wall surface of the through hole 6. The first resin insulating layer (20F) is formed in the recess (7F). In the embodiment, on the end surface (8B), there is a recess (back-side recess) (7B) surrounded by the end surface (8B) and the inner wall surface of the through hole 6. The first resin insulating layer (20B) is formed in the recess (7B).

A distance (L1) between the front surface (5F) and the end surface (8F) is less than 10 μm. A distance (L2) between the back surface (5B) and the end surface (8B) is less than 10 μm. The distance (L2) may be greater than the distance (L1).

The end surface (8F) may be formed of a bonding surface (front-side bonding surface) (50F) in contact with the first resin insulating layer (20F) and a connection surface (front-side connection surface) (52F) connected to the first via conductor (40F). The bonding surface (50F) may have a first unevenness (60F). The end surface (8F) and the first resin insulating layer (20F) may be bonded to each other via the first unevenness (60F) of the bonding surface (50F). The connection surface (52F) may have a second unevenness (62F). The connection surface (52F) may also be a substantially smooth surface. The first unevenness (60F) may have a size greater than that of the second unevenness (62F). The end surface (8B) may be formed of a bonding surface (back-side bonding surface) (50B) in contact with the first resin insulating layer (20B) and a connection surface (back-side connection surface) (52B) connected to the first via conductor (40B). The bonding surface (50B) may have a first unevenness (60B). The end surface (8B) and the first resin insulating layer (20B) may be bonded to each other via the first unevenness (60B) of the bonding surface (50B). The connection surface (52B) may have a second unevenness (62B). The connection surface (52B) may also be a substantially smooth surface. The first unevenness (60B) may have a size greater than that of the second unevenness (62B).

As illustrated in FIG. 2B, the end surface (8F) and the end surface (8B) may be curved surfaces. For example, a curved surface is formed by spraying an etching solution onto an end of the through-hole conductor 8. For example, the etching solution is sprayed onto the end such that a spray intensity decreases from the center of the end toward periphery of the end. The end surface (8F) may be formed of a curved surface such that the distance (L1) between the front surface (5F) and the end surface (8F) substantially increases from the periphery toward the center. The distance (L1) may be a shortest distance between the front surface (5F) and the end surface (8F). The bonding surface (50F) may be formed of a first curved surface (front-side first curved surface) (70F), and the connection surface (52F) may be formed of a second curved surface (front-side second curved surface) (72F). The first curved surface (70F) and the second curved surface (72F) may be formed of different curved surfaces. It is preferable that the first curved surface (70F) have a curvature smaller than that of the second curved surface (72F). The first curved surface (70F) is not necessarily formed by extending the second curved surface (72F). The end surface (8B) may be formed of a curved surface such that the distance (L2) between the back surface (5B) and the end surface (8B) substantially increases from the periphery toward the center. The distance (L2) may be a shortest distance between the back surface (5B) and the end surface (8B). The bonding surface (50B) may be formed of a first curved surface (back-side first curved surface) (70B), and the connection surface (52B) may be formed of a second curved surface (back-side second curved surface) (72B). The first curved surface (70B) and the second curved surface (72B) may be formed of different curved surfaces. The first curved surface (70B) is not necessarily formed by extending the second curved surface (72B). It is preferable that the first curved surface (70B) have a curvature smaller than that of the second curved surface (72B).

As illustrated in FIG. 2C, in the embodiment, there may be gaps (11F, 11B) having predetermined depths (D1, D2) between the through-hole conductor 8 and the inner wall surface of the through hole 6. The gap (11F) is a gap on the front surface (5F) side, and the gap (11B) is a gap on the back surface (5B) side. For example, center portions of the ends of the through-hole conductor 8 are covered with masks. After that, the gaps (11F, 11B) are formed by removing the ends of the through-hole conductor 8 that are exposed from the masks. Alternatively, the gaps (11F, 11B) may each be formed by removing a part of the seed layer (10a). The gap (11F) may be filled with the first resin insulating layer (20F), and the gap (11B) may be filled with the first resin insulating layer (20B). By filling the gaps (11F, 11B) with the first resin insulating layers (20F, 20B), the first resin insulating layers (20F, 20B) become less likely to peel off from the substrate 4.

The depth (D1) of the gap (11F) and the depth (D2) of the gap (11B) may be 10 μm or less. The depths (D1, D2) may be 5 μm or less. The depth (D2) may be greater than the depth (D1). (The Depth (D2))/(the depth (D1)) may be 1.2 or more and 1.5 or less. In the wiring substrate, the back side is farther from the mounting surface than the front side. Therefore, it is thought that the back side is more likely to warp than the front side. Therefore, it is thought that a resin insulating layer on the back side is more likely to peel off from the substrate 4. In the embodiment, since the depth (D2) is greater than the depth (D1), the first resin insulating layer (20B) is less likely to peel off from the substrate 4.

As illustrated in FIG. 1, the first resin insulating layer (20F) has a first surface (22F) and a second surface (24F) on an opposite side with respect to the first surface (22F). The first resin insulating layer (20F) is formed on the front surface (5F) of the substrate 4 such that the second surface (24F) faces the front surface (5F). In the example illustrated in FIG. 1, the second surface (24F) is in contact with the front surface (5F). The second surface (24F) is in contact with the bonding surface (50F) of the end surface (8F). No conductor circuit is present between the front surface (5F) and the second surface (24F). No conductor circuit is formed on the front surface (5F). The first resin insulating layer (20F) has a first opening (26F) reaching the end surface (8F) of the through-hole conductor 8. The first resin insulating layer (20F) is formed of a resin and a large number of inorganic particles dispersed in the resin. The resin is an epoxy resin. Examples of the resin include a thermosetting resin and a photocurable resin. The inorganic particles are glass particles. It is also possible that the inorganic particles are alumina particles. A content of the inorganic particles in the first resin insulating layer (20F) is 75 wt % or more.

The first conductor layer (30F) is formed on the first surface (22F) of the first resin insulating layer (20F). The first conductor layer (30F) includes a first signal wiring (32F), a second signal wiring (34F), and a land (36F). Although not illustrated in the drawings, the first conductor layer (30F) also includes conductor circuits other than the first signal wiring (32F), the second signal wiring (34F), and the land (36F). The first signal wiring (32F) and the second signal wiring (34F) form a pair wiring. The first conductor layer (30F) is mainly formed of copper. The first conductor layer (30F) is formed of a seed layer (30Fa) and an electrolytic plating layer (30Fb) on the seed layer (30Fa). The seed layer (30Fa) is formed by sputtering. The seed layer (30Fa) is formed of a first layer (31Fa) on the first surface (22F) and a second layer (31Fb) on the first layer (31Fa). The first layer (31Fa) is in contact with the first surface (22F). The first layer (31Fa) is formed of a copper alloy. A copper content in the copper alloy is 90 wt % or more. The second layer (31Fb) is formed of copper. The electrolytic plating layer (30Fb) is formed of copper.

The first resin insulating layer (20F) is formed on the glass substrate 4. Since glass is excellent in flatness, the first surface (22F) of the first resin insulating layer (20F) is also excellent in flatness. When no conductor circuit is formed between the front surface (5F) and the first resin insulating layer (20F), the first surface (22F) can follow the front surface (5F). The first surface (22F) can have flatness equivalent to that of the front surface (5F). In the embodiment, fine wirings can be formed on the first surface (22F). For example, the first conductor layer (30F) can have wirings having widths of 1.5 μm or more and 3.5 μm or less. A width of a space between adjacent wirings is 1.5 μm or more and 3.5 μm or less.

The first via conductor (40F) is formed in the first opening (26F). The first via conductor (40F) electrically connects the through-hole conductor 8 and the first conductor layer (30F). The first via conductor (40F) electrically connects the through-hole conductor 8 and the land (36F) of the first via conductor (40F). The first via conductor (40F) is formed of a seed layer (30Fa) and an electrolytic plating layer (30Fb) on the seed layer (30Fa). The seed layer (30Fa) that forms the first via conductor (40F) is common to the seed layer (30Fa) that forms the first conductor layer (30F). The electrolytic plating layer (30Fb) that forms the first via conductor (40F) is common to the electrolytic plating layer (30Fb) that forms the first conductor layer (30F). The seed layer (30Fa) that forms the first via conductor (40F) is formed of a first layer (31Fa) formed on an inner wall surface (27F) of the first opening (26F) and on the end surface (8F) of the through-hole conductor 8 exposed from the first opening (26F), and a second layer (31Fb) formed on the first layer (31Fa). In FIG. 1, the first via conductor (40F) is connected to the end surface (8F). The first via conductor (40F) is connected to the end surface (8F) via the connection surface (52F). The first layer (31Fa) is in contact with the end surface (8F) (connection surface (52F)) and the inner wall surface (27F) of the through-hole conductor 8. The first via conductor (40F) is formed directly on the end surface (8F). The first via conductor (40F) is directly connected to the end surface (8F).

The second resin insulating layer (120F) is formed on the first surface (22F) of the first resin insulating layer (20F) and on the first conductor layer (30F). The first conductor layer (30F) is formed between the second resin insulating layer (120F) and the first resin insulating layer (20F). The second resin insulating layer (120F) has a first surface (122F) and a second surface (124F) on an opposite side with respect to the first surface (122F). The second surface (124F) of the second resin insulating layer (120F) faces the first conductor layer (30F). Similar to the first resin insulating layer (20F), the second resin insulating layer (120F) is formed of a resin and inorganic particles. Therefore, the material of the second resin insulating layer (120F) is similar to the material of the first resin insulating layer (20F). The first surface (122F) of the second resin insulating layer (120F) is similar to the first surface (22F) of the first resin insulating layer (20F).

The second resin insulating layer (120F) has a second opening (126F) that exposes the first conductor layer (30F). The second opening (126F) exposes the land (36F).

The second conductor layer (130F) is formed on the first surface (122F) of the second resin insulating layer (120F). The second conductor layer (130F) and the first conductor layer (30F) are similar. Therefore, the second conductor layer (130F) has wirings similar to those of the first conductor layer (30F). Further, the second conductor layer (130F) is formed of a seed layer (130Fa) and an electrolytic plating layer (130Fb) on the seed layer (130Fa). The seed layer (130Fa) is formed of a first layer (131Fa) and a second layer (131Fb) on the first layer (131Fa).

The second via conductor (140F) is formed in the second opening (126F). The second via conductor (140F) electrically connects the first conductor layer (30F) and the second conductor layer (130F). In FIG. 1, the second via conductor (140F) electrically connects the land (36F) and a land (136F). The second via conductor (140F) and the first via conductor (40F) are similar. Therefore, the second via conductor (140F) is formed of a seed layer (130Fa) and an electrolytic plating layer (130Fb) on the seed layer (130Fa). The seed layer (130Fa) is formed of a first layer (131Fa) and a second layer (131Fb) on the first layer (131Fa).

The front-side build-up layer (300F) and the back-side build-up layer (300B) are similar. The first resin insulating layer (20B) has a first surface (22B) and a second surface (24B). The second resin insulating layer (120B) has a first surface (122B) and a second surface (124B). A detailed description of the other components of the back-side build-up layer (300B) is omitted.

Although not illustrated in the drawings, each side of the wiring substrate 2 has a length of 50 mm or more. The length of each side is preferably 100 mm or more. The length of each side is 250 mm or less. A length of a signal wiring formed according to the embodiment is 5 mm or more. The length of the signal wiring may be 10 mm or more and 20 mm or less.

### Method for Manufacturing Wiring Substrate

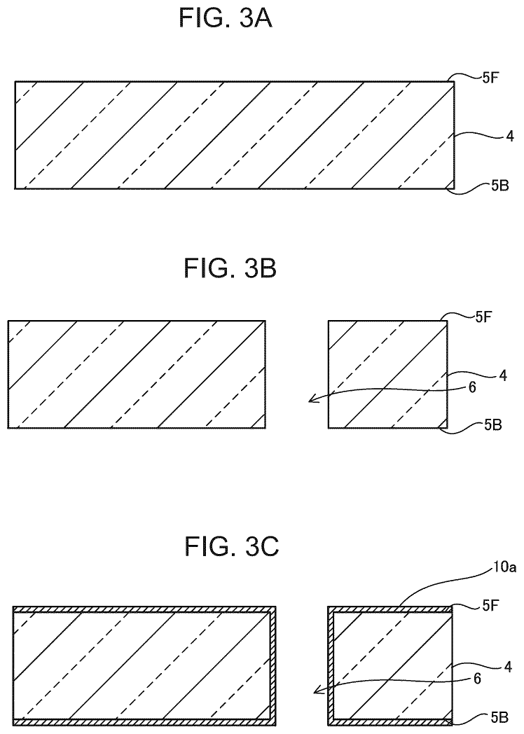

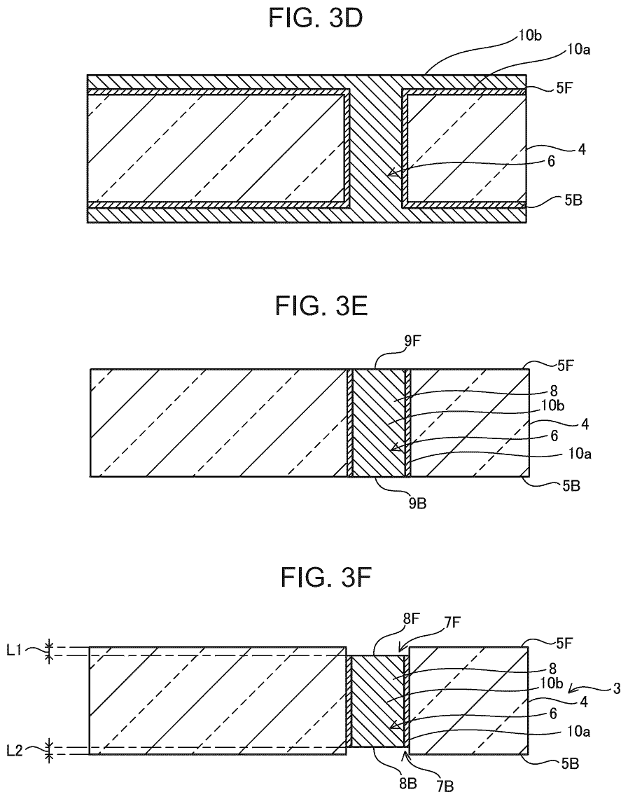

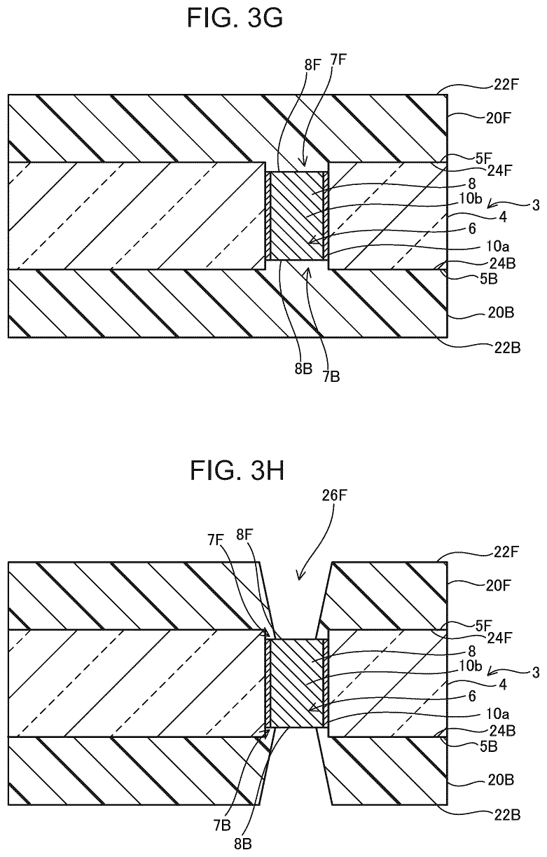

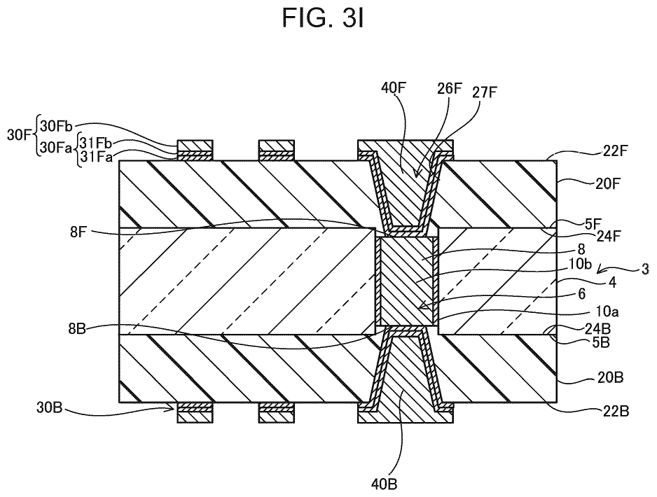

FIGS. 3A-3I illustrate a method for manufacturing the wiring substrate 2 of the embodiment. FIGS. 3A to 3I are cross-sectional views. FIG. 3A illustrates the glass substrate 4. The substrate 4 has the front surface (5F) and the back surface (5B). As illustrated in FIG. 3B, the through hole 6 is formed extending from the front surface (5F) to the back surface (5B). The through hole 6 penetrate the substrate 4. Laser is irradiated from the front surface (5F) side of the substrate 4. After that, the substrate 4 is immersed in a hydrofluoric acid. The through hole 6 is formed.

As illustrated in FIG. 3C, the seed layer (10a) is formed. The seed layer (10a) is formed by electroless plating. The seed layer (10a) is formed of an electroless copper plating film. The seed layer (10a) is formed on the inner wall surface of the through hole 6, on the front surface (5F), and on the back surface (5B).

As illustrated in FIG. 3D, the electrolytic plating layer (10b) is formed. The electrolytic plating layer (10b) is formed on the seed layer (10a). The electrolytic plating layer (10b) fills the through hole 6. The electrolytic plating layer (10b) is formed of an electrolytic copper plating film.

As illustrated in FIG. 3E, the electrolytic plating layer (10b) and the seed layer (10a) on the front surface (5F) are removed by polishing. The electrolytic plating layer (10b) and the seed layer (10a) on the back surface (5B) are removed by polishing. The front surface (5F) and the back surface (5B) of the substrate (4) are exposed. The through-hole conductor 8 is formed by the seed layer (10a) on the inner wall surface of the through hole 6 and the electrolytic plating layer (10b) on the seed layer (10a). An end (9F) of the through-hole conductor 8 on the front surface (5F) side is exposed from the front surface (5F). The end (9B) of the through-hole conductor 8 on the back surface (5B) side is exposed from the back surface (5B). A surface forming the end (9F) and the front surface (5F) form the same plane. A surface forming the end (9B) and the back surface (5B) form the same plane.

The end (9F) and end (9B) of the through-hole conductor 8 are dissolved by an etching solution. A part of the through-hole conductor 8 near the end (9F) is removed. A part of the through-hole conductor 8 near the end (9B) is removed. For example, the two removals may be performed separately. In the embodiment, the distance (L1) can be made smaller than the distance (L2). For example, the two removals are performed at the same time. In the embodiment, the distance (L1) and the distance (L2) can be made substantially the same. As illustrated in FIG. 3F, the end surface (8F) on the front surface (5F) side and the end surface (8B) on the back surface (5B) side of the through-hole conductor 8 are formed. The core substrate 3 is formed. The end surface (8F) is formed below the front surface (5F). The end surface (8B) is formed below the back surface (5B). The recess (7F) surrounded by the end surface (8F) and the inner wall surface of the through hole 6 is formed. The recess (7B) surrounded by the end surface (8B) and the inner wall surface of the through hole 6 is formed. The distance (L1) is preferably smaller than 3 μm. The distance (L2) is preferably smaller than 3 μm.

Since the front-side build-up layer (300F) and the back-side build-up layer (300B) are manufactured in a similar manner, a description of the method for manufacturing the back-side build-up layer (300B) is omitted.

As illustrated in FIG. 3G, the first resin insulating layer (20F) is formed on the front surface (5F) of the substrate (4) and on the end surface (8F). The second surface (24F) of the first resin insulating layer (20F) faces the front surface (5F) of the substrate (4). The first resin insulating layer (20F) is formed in the recess (7F). The first resin insulating layer (20F) fills the recess (7F). The first surface (22F) is formed as a substantially flat surface. The front surface (5F) and the first surface (22F) are substantially parallel to each other.

Laser is irradiated from above the first surface (22F) of the first resin insulating layer (20F). The laser penetrates the first resin insulating layer (20F). The laser is, for example, UV laser or CO₂ laser. As illustrated in FIG. 3H, the first opening (26F) for a via conductor reaching the end surface (8F) of the through-hole conductor 8 is formed. The end surface (8F) of the through-hole conductor 8 is exposed from the first opening (26F).

The seed layer (30Fa) is formed on the first surface (22F) of the first resin insulating layer (20F). The seed layer (30Fa) is formed by sputtering. The formation of the seed layer (30Fa) is performed by a dry process. The seed layer (30Fa) is also formed on the end surface (8F) of the through-hole conductor 8 exposed from the first opening (26F) and on the inner wall surface (27F) of the first opening (26F). The seed layer (30Fa) is mainly formed of copper. The first layer (31Fa) is formed on the first surface (22F) by sputtering. The first layer (31Fa) is formed by sputtering on the inner wall surface (27F) exposed from the first opening (26F) and on the end surface (8F) of the through-hole conductor 8. The second layer (31Fb) is formed by sputtering on the first layer (31Fa).

A plating resist is formed on the seed layer (30Fa). The electrolytic plating layer (30Fb) is formed on the seed layer (30Fa) exposed from the plating resist. The electrolytic plating layer (30Fb) fills the first opening (26F).

The plating resist is removed. The seed layer (30Fa) exposed from the electrolytic plating layer (30Fb) is removed. As illustrated in FIG. 3I, the first conductor layer (30F) and the first via conductor (40F) are formed at the same time.

The second resin insulating layer (120F) is formed on the first surface (22F) of the first resin insulating layer (20F) and on the first conductor layer (30F). The second conductor layer (130F) is formed on the first surface (122F) of the second resin insulating layer (120F). The second via conductor (140F) is formed in the second opening (126F) of the second resin insulating layer (120F). The second resin insulating layer (120F) is formed using the same method as the first resin insulating layer (20F). The second conductor layer (130F) is formed using the same method as the first conductor layer (30F). The second via conductor (140F) is formed using the same method as the first via conductor (40F). The wiring substrate 2 of the embodiment is obtained. The front-side build-up layer (300F) is formed on the front surface (5F) and the end surface (8F). The back-side build-up layer (300B) is formed on the back surface (5B) and the end surface (8B).

In the wiring substrate 2 of the embodiment, the end surface (8F) of the through-hole conductor 8 is formed below the front surface (5F) of the substrate 4. The end surface (8B) of the through-hole conductor 8 is formed below the back surface (5B) of the substrate 4. When the first resin insulating layers (20F, 20B) are laminated on the core substrate 3, even when the through-hole conductor 8 thermally expands, the through-hole conductor 8 does not press the first resin insulating layers (20F, 20B). Alternatively, even when the through-hole conductor 8 presses the first resin insulating layers (20F, 20B), the pressing force is weak. Therefore, in the embodiment, occurrence of a crack in the first resin insulating layers (20F, 20B) can be suppressed. When the first resin insulating layers (20F, 20B) are laminated on the core substrate 3, even when the through-hole conductor 8 thermally expands, the through-hole conductor 8 does not press the substrate 4. Alternatively, even when the through-hole conductor 8 presses the substrate 4, the pressing force is weak. Therefore, in the embodiment, occurrence of a crack in the substrate 4 can be suppressed. In the embodiment, on the end surface (8F) of the through-hole conductor 8, there is the recess (7F) surrounded by the end surface (8F) and the wall surface of the through hole 6. The first resin insulating layer (20F) is formed in the recess (7F). Since a contact area between the first resin insulating layer (20F) and the substrate 4 is large, the first resin insulating layer (20F) is less likely to peel off from the substrate 4.

Japanese Patent Application Laid-Open Publication No. 2024-118643 describes a wiring substrate having a core substrate and build-up layers formed on front and back sides of the core substrate. The core substrate is formed of a substrate made of glass and a through-hole conductor penetrating the substrate. The entire contents of this publication are incorporated herein by reference.

In Japanese Patent Application Laid-Open Publication No. 2024-118643, a surface of the substrate and an upper end of the through-hole conductor form the same plane. Copper forming the through-hole conductor has a larger CTE (coefficient of thermal expansion) than that of glass forming the substrate. Therefore, when a resin insulating layer forming a build-up layer is laminated on the surface of the core substrate, it is thought that the upper end of the through-hole conductor protrudes above the surface of the substrate due to thermal expansion. Alternatively, it is thought that the protrusion is suppressed by pressure during lamination. Therefore, it is thought that the through-hole conductor expands in a direction parallel to the surface of the substrate. It is thought that a crack occurs in at least one of the resin insulating layer and the substrate.

A wiring substrate according to an embodiment of the present invention includes: a core substrate that has a substrate made of glass, a through hole penetrating the substrate, and a through-hole conductor formed in the through hole; a resin insulating layer that is formed on the core substrate, and has a first surface, a second surface on an opposite side with respect to the first surface, and an opening for a via conductor extending from the first surface to the second surface; a first conductor layer that is formed on the first surface of the resin insulating layer; and a via conductor that is formed in the opening and is electrically connected to the through-hole conductor. An end surface of the through-hole conductor is formed below a surface of the substrate.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a core substrate comprising a through-hole conductor;
a resin insulating layer formed on the core substrate;
a first conductor layer formed on a surface of the resin insulating layer; and
a via conductor formed in the resin insulating layer such that the via conductor is connected to the through-hole conductor of the core substrate,
wherein the core substrate is formed such that the core substrate includes a substrate comprising glass and the through-hole conductor formed in the substrate and that the through-hole conductor has an end surface formed below a surface of the substrate.

2. The wiring substrate according to claim 1, wherein the core substrate is formed such that a distance between the surface of the substrate and the end surface of the through-hole conductor is less than 10 μm.

3. The wiring substrate according to claim 1, wherein the core substrate is formed such that the end surface of the through-hole conductor includes a connection surface connected to the via conductor and a bonding surface being in contact with the resin insulating layer and having an unevenness such that the unevenness of the bonding surface is configured to bond the end surface to the resin insulating layer.

4. The wiring substrate according to claim 3, wherein the core substrate is formed such that the connection surface in the end surface of the through-hole conductor has a second unevenness such that the unevenness of the bonding surface is larger than the second unevenness of the connection surface.

5. The wiring substrate according to claim 1, wherein the core substrate is formed such that the end surface of the through-hole conductor is a curved surface.

6. The wiring substrate according to claim 5, wherein the core substrate is formed such that the end surface of the through-hole conductor includes a connection surface connected to the via conductor and comprising a second curved surface and a bonding surface being in contact with the resin insulating layer and comprising a first curved surface different from the second curved surface.

7. The wiring substrate according to claim 6, wherein the end surface of the through-hole conductor in the core substrate is formed such that the first curved surface of the boding surface is not formed by extending the second curved surface of the connection surface.

8. The wiring substrate according to claim 1, wherein the core substrate is formed such that a gap having a depth is formed between the through-hole conductor and an inner wall surface of a through hole in which the through-hole conductor is formed and that the gap is filled with resin from the resin insulating layer.

9. The wiring substrate according to claim 8, wherein the core substrate is formed such that the depth of the gap is formed 10 μm or less.

10. The wiring substrate according to claim 8, wherein the core substrate is formed such that the depth of the gap is formed 5 μm or less.

11. The wiring substrate according to claim 8, wherein the core substrate is formed such that the core substrate has a front surface and a back surface on an opposite side with respect to the front surface, the front surface is formed closer to a mounting surface of the wiring substrate than the back surface, the gap includes a gap on the front surface side and a gap on the back surface side, and a depth of the gap on the back surface side is greater than a depth of the gap on the front surface side.

12. The wiring substrate according to claim 11, wherein the core substrate is formed such that a ratio of the depth of the gap on the back surface side to the depth of the gap on the front surface side is in a range of 1.2 or more and 1.5 or less.

13. The wiring substrate according to claim 2, wherein the core substrate is formed such that the end surface of the through-hole conductor includes a connection surface connected to the via conductor and a bonding surface being in contact with the resin insulating layer and having an unevenness such that the unevenness of the bonding surface is configured to bond the end surface to the resin insulating layer.

14. The wiring substrate according to claim 13, wherein the core substrate is formed such that the connection surface in the end surface of the through-hole conductor has a second unevenness such that the unevenness of the bonding surface is larger than the second unevenness of the connection surface.

15. The wiring substrate according to claim 2, wherein the core substrate is formed such that the end surface of the through-hole conductor is a curved surface.

16. The wiring substrate according to claim 15, wherein the core substrate is formed such that the end surface of the through-hole conductor includes a connection surface connected to the via conductor and comprising a second curved surface and a bonding surface being in contact with the resin insulating layer and comprising a first curved surface different from the second curved surface.

17. The wiring substrate according to claim 16, wherein the end surface of the through-hole conductor in the core substrate is formed such that the first curved surface of the boding surface is not formed by extending the second curved surface of the connection surface.

18. The wiring substrate according to claim 2, wherein the core substrate is formed such that a gap having a depth is formed between the through-hole conductor and an inner wall surface of a through hole in which the through-hole conductor is formed and that the gap is filled with resin from the resin insulating layer.

19. The wiring substrate according to claim 18, wherein the core substrate is formed such that the depth of the gap is formed 10 μm or less.

20. The wiring substrate according to claim 18, wherein the core substrate is formed such that the depth of the gap is formed 5 μm or l
